(19) United States
(12) Patent Application Publication
(10) Pub. No.: US 2017/0051192 A1
(43) Pub. Date: Feb. 23, 2017

(54) FLEXIBLE COMPOSITES CONTAINING GRAPHITE AND FILLERS

(71) Applicants: Jeffri J. NARENDRA, Indonesion (ID); Hiroyuki Fukushima, Japan (JP); Thomas Griffin Ritch, III, East Lansing, MI (US)

(72) Inventors: Jeffri J. NARENDRA, Indonesion (ID); Hiroyuki Fukushima, Japan (JP); Thomas Griffin Ritch, III, East Lansing, MI (US)

(21) Appl. No.: 15/332,338

(22) Filed: Oct. 24, 2016

Related U.S. Application Data
(63) Continuation of application No. 14/488,417, filed on Sep. 17, 2014.

(51) Int. Cl. C09K 5/14; H05K 7/20; F28F 21/02

(52) U.S. Cl. CPC C09K 5/14; F28F 21/02; H05K 7/20481; F28F 2255/02; F28F 2013/001

(57) ABSTRACT

Resin-free, flexible composites of graphite leaf, containing fillers other than natural graphite, which has higher thermal conductivity than conventional 100% natural graphite based graphite sheet/foil/paper, and methods of preparing such flexible composites. In a second embodiment, there is a thermal management system comprising at least one flexible composite as set forth just above, wherein a graphite surface of a flexible composite is in thermal contact with a heat source of a heat generating device.

This application is a utility application claiming priority from U.S. utility application Ser. No. 14/438,417, filed Sep. 17, 2014 which is a utility application filed from Provisional Application Ser. No. 61/879,225, Filed Sep. 18, 2013.

### BACKGROUND OF THE INVENTION

Natural graphite based graphite sheets or foils made of expanded natural graphite have been used for many years in thermal spreading and thermal managing application in portable electronics and LEO devices. Typically these sheets or foils have limited thermal conductivity in the range of 100 to 400 W/mK.

Recently, more and more devices require better heat management systems due to increased heat generation. Such devices include portable electronics, LED devices, industrial devices, medical devices, military devices, aerospace vehicle systems, automotive vehicle systems, and train systems.

For example, as the recent electronics and LED devices achieve higher performance, these devices also produce more heat during their operations. At the same time, the thickness of portable devices gets thinner, and each part of device, including the heat spreader, needs to be thinner.

For another example, in an automotive vehicle, more efficient heating/cooling system is required to utilize the energy more efficiently while not sacrificing comfort level. In this case, a heat spreader which has a thicker thickness with higher heat transfer is required. Also, recent developments in battery technology require better heat management in case of catastrophic thermal runaway. In this case, a thermal sheet with high thermal conductivity, which also can be formed in a different form than plain sheet, is required. In response to these challenges, the instant invention addresses a higher thermal conductivity material which can be made in a wide variety of thicknesses. By “higher” it is meant that the thermal conductivity is higher than conventional graphite thermal sheets.

U.S. Pat. No. 3,404,061, deals with flexible graphite material of expanded particles compressed together, in which expanded graphite particles are compressed together in the absence of a binder. The resulting sheet is made of 100% graphite, which is different from the instant invention.

U.S. Pat. No. 4,826,181 deals with a seal utilizing composites of flexible graphite particles and amorphous carbon, in which a binder is mixed with flexible graphite particles and then molded into the desired shape. The molded shape of binder and flexible graphite particles is baked at a temperature so that the binder is carbonized to form amorphous carbon. In this case, the formed amorphous carbon does not have high thermal conductivity and the resulted composite is not suitable for thermal management application. In fact, the patent does not describe thermal management as the target application.

U.S. Pat. No. 5,149,518 deals with an ultra-thin flexible graphite calendared sheet and method of manufacture, in which expanded natural graphite is compressed by pressure rolls, and then dried in a furnace at at least 2000° F. to form a flexible sheet. The resulting sheet is made of virtually 100% natural graphite with trace amounts of impurities coming from the natural graphite source. This invention is different from the instant invention in the way that the instant invention utilized other fillers intentionally to achieve the claimed structure and performance.

U.S. Pat. No. 6,087,034 deals with a flexible graphite composite, in which a flexible graphite sheet with embedded ceramic fibers extending its opposite planar surfaces into the sheet to provide permeability of the sheet to gasses. Such a structure, however, does not achieve higher thermal conductivity and the claimed application is an electrode used in a fuel cell.

U.S. Pat. No. 8,034,451 deals with a graphite body wherein the graphite body comprises aligned graphite flakes bonded with a binder, in which the graphite has an average particle size of >200 mu m; formed by carbonizing and optionally graphitizing the body; high thermal conductivity, high thermal anisotropy; suitable for use as heat spreaders, in which a graphite body is comprised of aligned graphite flakes bonded with a binder, then the binder is carbonized and optionally graphitized.

In this case the formed amorphous carbon does not have high thermal conductivity and the resulting composite is not suitable for thermal management applications. When the amorphous carbon is graphitized, the resulting structure is 100% graphite, which differs from the instant invention.

U.S. Pat. No. 5,296,310 deals with a high conductivity hybrid material for thermal management, in which a hybrid structural material with layered structure is claimed. This is different from the instant invention in the way that the instant invention is a one-piece composite consisting of multiple fillers.

U.S. Pat. No. 5,542,471 deals with a heat transfer element having thermally conductive fibers, in which said heat transfer element consists of a heat element comprising a plate having a first side and second side and being comprised of heat conducting fibers extending longitudinally from said first side to said second side. This is different from the instant invention in the way that the instant invention is a one-piece composite consisting of multiple fillers with no specific alignment.

U.S. Pat. No. 5,766,765 deals with generally fiat members having smooth surfaces and made of highly oriented graphite, in which an element for an apparatus is made of highly oriented pyrolytic graphite. The highly oriented pyrolytic graphite is formed by graphitizing a polymer film, typically a polyimide film, at very high temperature, typically over 2000° C. The process is totally different from the instant invention.

U.S. Pat. No. 5,863,467 deals with a high thermal conductivity composite and method, in which a method of forming a machinable composite of high thermal conductivity comprises the steps of combining particles of highly oriented graphite flakes with a binder, then the binder is polymerized under compression to form a machinable solid composite structure. The instant invention does not use polymer resins to form a solid one piece structure, thus, differs from this prior art.

U.S. Pat. No. 6,503,626 deals with a graphite-based heat sink, in which a graphite article is formed from comminuted resin-impregnated flexible natural graphite sheet compressed into desired shape. The current invention does not use polymer resins to form a solid one piece structure, thus, differs from this previous art. US20060029805; High thermal conductivity graphite and method of making, in which a high thermal conductivity graphite article is made by dry mixing graphite filler and a binder and heat-treated to form a solid article. The current invention does not use polymer resins to form a solid one piece structure, thus, differs from this previous art.

U.S. Pat. No. 4,961,988 deals with a process that includes embedding with auxiliary material and bonding, in which a general packing of expanded graphite comprising mainly the vermiform laminae of expanded graphite and auxiliary materials in which the auxiliary materials are pre-treated with organic adhesive is claimed. The examples show this material is formed in a dry process. The instant invention is different from this prior art in a way that a composite is formed by a wet process as opposed to this prior art. Also the current invention does not use pre-treated auxiliary materials.

U.S. Pat. No. 6,254,993 deals with a flexible graphite sheet with decreased anisotropy, in which flexible graphite sheet is made by compressing a mixture of relatively large particles of intercalated, exfoliated, expanded natural graphite with smaller particles of intercalated, exfoliated expanded particles of natural graphite. This prior art is different from the instant invention in the way that the flexible graphite sheet described in the prior art consists of 100% graphite. The instant invention is a composite with a mixture of graphite and other fillers.

U.S. Pat. No. 6,432,336 deals with a flexible graphite article and method of manufacture, in which a method for the continuous production of resin-impregnated flexible graphite sheet is claimed. The instant, invention does not use resin, thus, differs from this prior art.

U.S. Pat. No. 6,673,284 deals with a method of making flexible graphite sheet having increased isotropy, in which a flexible graphite sheet is formed with 100% graphite and further processed to introduce increased isotropy. The resulting sheet consists of 100% graphite, which is different from the instant invention.

WO 1998041486 deals with a flexible graphite composite sheet and method, in which a flexible graphite sheet is formed with two expanded natural graphites with different size range. The resulting sheet consists of 100% graphite, which is different from the instant invention.

WO 2000064808 deals with a flexible graphite article and method of manufacturing, in which ceramic fiber particles are admixed into a flexible graphite sheet to enhance isotropy. The instant invention utilizes fillers including fibers, however, it is not intended to enhance the isotropy of a flexible thermal sheet, and thus, the sheet still maintains the higher in-plane thermal conductivity than conventional flexible graphite sheets.

EPO 205970A2 deals with a process for producing graphite films, in which a process for producing a graphite film and fiber by graphitizing a film or fiber of polymer by high heat treatment is disclosed. The method of the instant invention uses a wet process to form a flexible graphite sheet, which is totally different from this prior art.

### THE INVENTION

What is disclosed and claimed herein are resin-free, flexible composites of graphite leaf, containing fillers, and methods of preparing such flexible composites containing non-natural graphite fillers selected from the group consisting of essentially of one or more fillers selected from groups consisting of fibers, fibrils, powders, particles, and Flakes. As used herein, “leaf” is graphite sheet or foils collectively referred to as “leaf”.

In a second embodiment, there is a thermal management system comprising at least one flexible composite as set forth just Supra, wherein the graphite rich surface of the flexible composite is in thermal contact with a heat source.

### BRIEF DESCRIPTION OF THE DRAWINGS

FIG. 1 is a picture of a flexible sheet consisting of graphite and filler, bent 180 degrees without damage, prepared from example 1.

FIG. 2 is a picture of a flexible sheet consisting of graphite and filler, bent into a free standing form prepared from example 1.

FIG. 3 is a scanning electron microscope image at 100× resolution, showing a flexible composite consisting of graphite and sodium carboxymethyl cellulose from example 1. It should be noted that the sheet surface is homogeneous.

FIG. 4 is a scanning electron microscope image at 65× resolution, showing a flexible composite consisting of graphite and Kevlar fibers. Kevlar® is a registered trademark owned by DuPont, Wilmington, Del. Kevlar fibers are visible on the surface, passing between the graphite platelets prepared from example 2.

FIG. 5 is a scanning electron microscope image at 100× resolution, showing a flexible composite consisting of graphite, Kevlar fibers, and sodium carboxymethyl cellulose prepared from example 3. Kevlar fibers are visible on the surface, otherwise it is homogeneous.

FIG. 6 is a scanning electron microscope image at 1000× resolution, showing a flexible composite consisting of graphite and fine cellulose fibers prepared in example 4. The impact of cellulose fibers on surface structure can be seen.

FIG. 7 is a scanning electron microscope image at 60× resolution, showing a flexible composite consisting of graphite and carbon fibers prepared from example 5. The carbon fibers can be seen passing between the graphite platelets.

FIG. 8 is a conventional graphite Paper 1 image by scanning electron microscope image at 500× resolution, showing Tgon 805 graphite paper from Laird Technologies. Homogeneous surface, with some visible roughness.

FIG. 9 is a conventional graphite Paper 2 image by scanning electron microscope image at 100× resolution, showing eGRAF SS400 graphite paper from Graphtec. Visible defects are due to storage, surface is homogeneous.

FIG. 10 is a conventional graphite paper 3 image by scanning electron microscope image at 100× resolution, showing T62 graphite paper from T-Global. The surface is homogeneous.

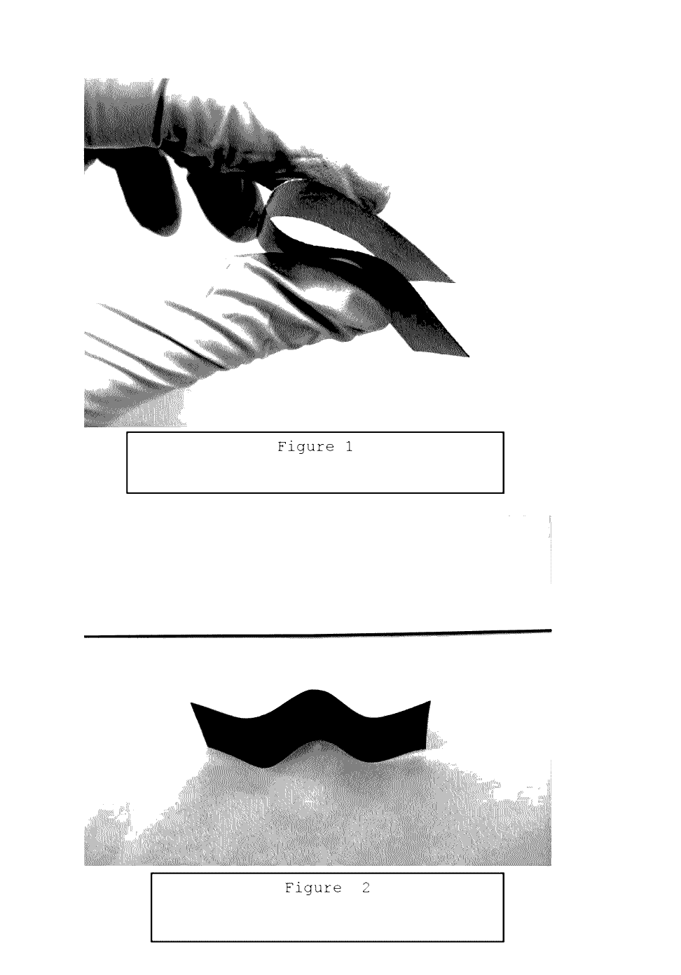

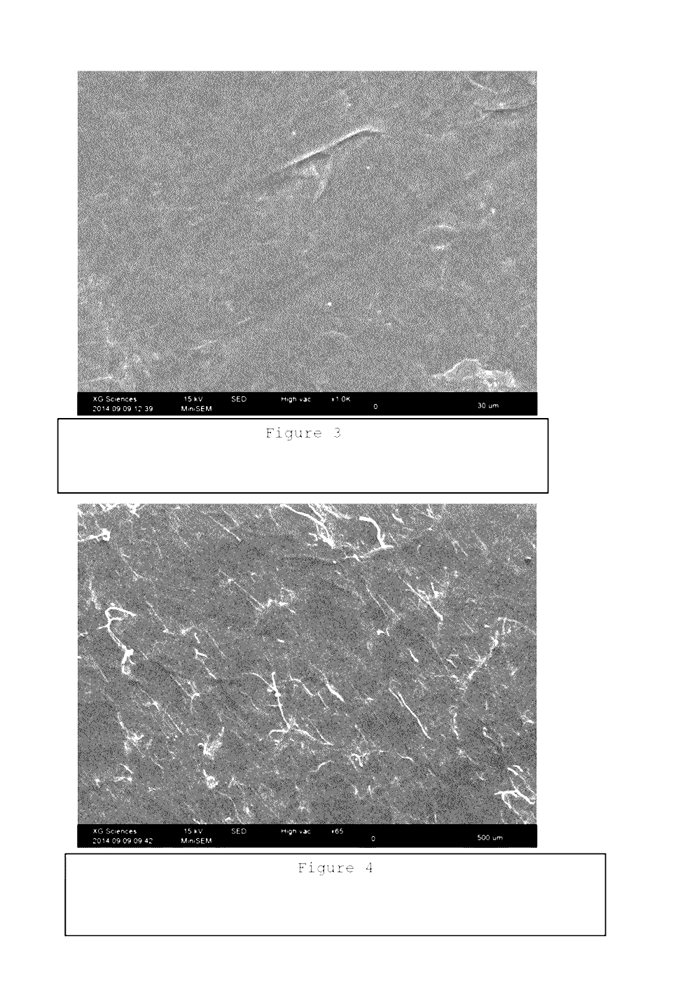

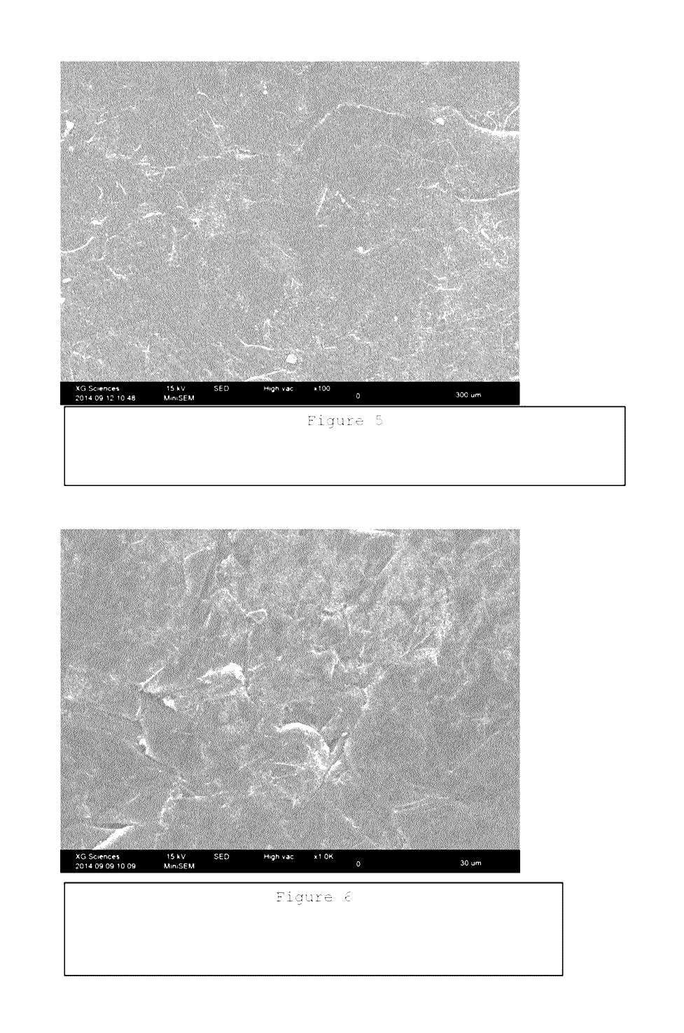

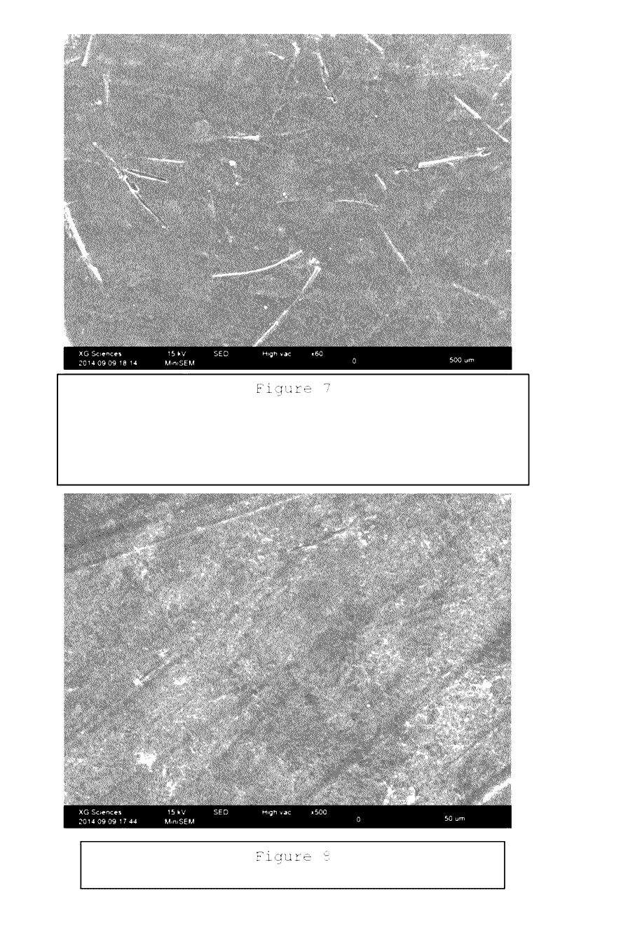

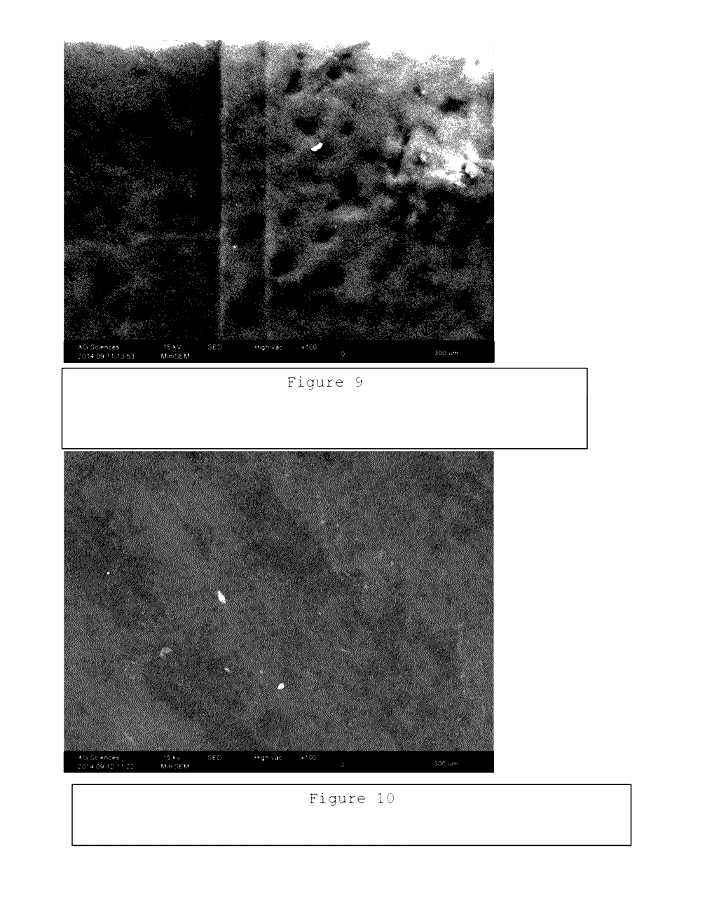

### DETAILED DESCRIPTION OF THE INVENTION

The object, of this invention is to provide thermal composites; with higher thermal conductivity than conventional graphite based graphite leaf made of 100% natural graphite while keeping the necessary flexibility and handling ability for the target applications. In addition to these advantages, this invention also offers better processability to various shapes which is often required for many thermal management systems.

The graphite used in the current invention may be from natural or synthetic sources, although natural graphite is preferred. Also, the thickness can be controlled in a wide range.

Many resin impregnated composites exist, in the prior art, but these materials form polymer based composites with lower thermal conductivity which cannot be effectively used in thermal management systems.

This instant invention offers flexible thermal composites which dissipate more heat than conventional 100% natural graphite based sheets or foil. Also the flexible thermal composites can be fitted, into many applications such as advanced portable electronic devices, LED devices, industrial devices, medical devices, military devices, and transportation devices due to the adoptability of a wide range of thickness while maintaining higher thermal conductivity than conventional graphite sheets or foils.

Graphite sheet is known to have good thermal spreading ability. By incorporating fibrous material, the characteristic property of graphite leaf can be tailored toward a specific need in terms of thermal conductivity, thickness, structure, flexibility, and mechanical properties.

What has been discovered and developed are flexible thermal composites comprising graphite and other fiber/fibrous/powder/flake materials which have thermal conductivity of over 400 W/mK, in some cases over 500 W/mK. Also the newly invented flexible composites have enough strength and processability so that they can be formed into various shapes while the thickness can be controlled from 5 um to over 200 um.

One aspect, of uniqueness of this invention is the manufacture of the graphite composite in a process which enables one to incorporate a variety of fibers, fibrils, particles, and flakes in a graphite sheet. The products of this invention are useful in industrial devices, such as motors, HVAC systems, and the like, medical devices such as neonatal intensive care units, and the like, military devices, such as missile electronics, such as unmanned and manned aerial vehicle platforms, and the like, automotive vehicles, such as EVs, plug-in hybrids, and the like, and devices for train systems, such as motors and the like.

The non-natural fillers of this invention are used at 0.1 weight percent to 80 weight percent based on the total weight of the graphite and the non-natural graphite fillers, especially useful are 0.5 to 60 weight percent and preferred are 1 weight, percent to 40 weight percent. Most preferred are 2 weight percent to 30 weight percent.

The thickness of the flexible composite ranges from 5μm to 1000 μm. especially useful is a thickness of 10 μm to 800 μm and preferred thicknesses are 15 μm to 600 μm with thicknesses of 20 μm to 400 μm being the most useful and most preferred are thicknesses of 25 μm to 300 μm.

It has been discovered that the flexible composites of this invention have in-plane thermal conductivity higher than 400 W/mK. It has also been discovered that if the graphite and non-natural fillers are heterogeneous across the width of the composite, extraordinary properties can be obtained.

It is contemplated within the scope of this invention to provide composites in which one side of the composite has more graphite in it as opposed to non-natural filler, while the opposite side of the composite has more non-natural filler than graphite in it.

Also, the invention provides a flexible composite comprising two natural graphite layers and two non-natural filler materials wherein the two graphite layers are in contact with two individual thermal sources.

### EXAMPLES

Data from the examples can be found in Table I, infra.

### Example 1

Natural flake graphite is treated with a strong acid and an oxidizing agent to form an intercalation compound. The intercalated graphite is washed with water and dried. The intercalated graphite is expanded at high temperature to many times its original thickness; the resulting material is generally referred to as graphite worms or vermiform graphite.

These worms were broken up and dispersed by blending in an aqueous slurry consisting of 2 liters of water, 12 grams graphite worms, 10 grams of pre-dissolved sodium carboxymethyl cellulose (CMC). This slurry is then filtered through a mesh of controlled size and properties in order to leave behind a uniform sheet of graphene nanoplatelets with CMC uniformly distributed throughout. If the slurry is partially segregated, it forms heterogeneous materials that will form a heterogeneous composite. The mesh material is chosen such that the graphite and CMC do not adhere to it when water is removed. The graphite-CMC sheet is transferred off of the mesh and dried into a green state.

The green state was then dried and went into a densification process in which pressure and heat were applied. The pressure can be applied using calendaring roll in a multiple succession. The nip pressure of the calendar ranged from 500-4500 PLI. An infrared oven was used to heat the material with temperatures ranging from 300-1500° F. This densification process was done in one stage or in multiple stages to reach the desired material density which ranged from 1.1-2.0 gr/cm³.

### Example 2

Natural flake graphite was treated with a strong acid and an oxidizing agent to form an intercalation compound. The intercalated graphite was washed with water and dried. The intercalated graphite was expanded at high temperature to many times its original thickness; the resulting material is generally referred to as graphite worms or vermiform graphite.

These worms were broken up and dispersed by blending in an aqueous slurry consisting of 2 liters water, 10.2 grams graphite worms, 1.8 grams of pre-dispersed Kevlar® fibers or fibrils, and 0.01 grams of surfactants and other process additives. This slurry was filtered through a mesh of controlled size and properties in order to leave behind a uniform sheet of graphene nanoplatelets with Kevlar uniformly distributed throughout. The mesh material was chosen such that the graphite and Kevlar did not adhere to it when water was removed. The graphite-Kevlar sheet was transferred off of the mesh and dried into a green state.

The green state was then dried and went into a densification process in which pressure and heat were applied. The pressure was applied using a calendaring roll in multiple successions. The nip pressure of the calendar ranged from 500-4500 PLI. An infrared oven was used to heat, the material with temperatures ranging from 300-1500° F. This densification process was done in one stage or in multiple stages to reach the desired material density which ranged from 1.1-2.0 gr/cm³.

### Example 3

Natural flake graphite was treated with a strong acid and an oxidizing agent to form an intercalation compound. The intercalated graphite was washed with water and dried. The intercalated graphite was expanded at high temperature to many times its original thickness; the resulting material being generally referred to as graphite worms or vermiform graphite.

These worms were broken up and dispersed by blending in an aqueous slurry consisting of 2 liters of water, 11.4 grams graphite worms, 0.6 grams of pre-dispersed Kevlar fibers or fibrils, and 10 grams of pre-dissolved CMC. This slurry was filtered through a mesh of controlled size and properties in order to leave behind a uniform sheet of graphene nanoplatelets with Kevlar uniformly distributed throughout. The mesh material was chosen such that the graphite, CMC and Kevlar do not adhere to it when water was removed. The graphite-CMC-Kevlar sheet is transferred off of the mesh and dried into a green state.

The green state was then dried and went into a densification process in which pressure and heat were applied. The pressure was applied using a calendaring roll in multiple successions. The nip pressure of the calendar ranged from 500-4500 PLI. An infrared oven was used to heat the material with temperatures ranging from 300-1500° F. This densification process was done in one stage or in multiple stages to reach the desired material density which ranged from 1.1-2.0 gr/cm³.

### Example 4

Natural flake graphite was treated with a strong acid and an oxidizing agent to form an intercalation compound. The intercalated graphite was washed with water and dried. The intercalated graphite was expanded at high temperature to many times its original thickness; the resulting material is generally referred to as graphite worms or vermiform graphite.

These worms were broken up and dispersed by blending in an aqueous slurry consisting of 2 liters of water, 10.2 grams graphite worms, 1.8 grams of cellulose fibers, and 0.01 grams of surfactant and other process additives. This slurry was filtered through a mesh of controlled size and properties in order to leave behind a uniform sheet of graphene nanoplatelets with cellulose uniformly distributed throughout. The mesh material was chosen such that the graphite and cellulose did not adhere to it when water was removed. The graphite-cellulose sheet was transferred off of the mesh and dried into a green state.

The green slate was then dried and went into a densification process in which pressure and heat were applied. The pressure was applied using a calendaring roll in multiple successions. The nip pressure of the calendar ranged from 500-4500 PLI. An infrared oven was used to heat the material with temperatures ranging from 300-1500° F. This densification process was done in one stage or in multiple stages to reach the desired material density which ranged from 1.1-2.0 gr/cm³.

### Example 5

Natural flake graphite was treated with a strong acid and an oxidizing agent to form an intercalation compound. The intercalated graphite was washed with water and dried. The intercalated graphite was expanded at high temperature to many times its original thickness; the resulting material being generally referred to as graphite worms or vermiform graphite.

These worms were broken up and dispersed by blending in an aqueous slurry consisting of 2 liters of water, 8.4 grams graphite worms, 3.6 grams of carbon fibers, and 0.01 grams of surfactant and other process additives. This slurry was filtered through a mesh of controlled size and properties in order to leave behind a uniform sheet of graphene nanoplatelets with carbon fiber uniformly distributed throughout. The mesh material was chosen such that the graphite and carbon fiber did not adhere to it when water was removed. The graphite-carbon fiber sheet was transferred off of the mesh and dried into a green state.

The green state was then dried and went into a densification process in which pressure and heat were applied. The pressure was applied using a calendaring roll in multiple successions. The nip pressure of the calendar ranged from 500-4500 PLI. An infrared oven was used to heat, the material with temperatures ranging from 300-1500° F. This densification process was done in one stage or in multiple stages to reach the desired material density which ranged from 1.1-2.0 gr/cm³.

### Conventional Graphite Paper 1

The Tgon 800 series made by Laird Technologies are 100% natural graphite papers sold as thermal interface pads. The sample tested was a Tgon 805 sheet 125 microns (5 mils) thick.

### Conventional Graphite Paper 2

The eGFAF Spreader Shield series made by Graphtec are 100% natural graphite papers sold as hear, spreaders. The sample tested was an SS400 sheet about 60 microns thick (about 2 mils).

### Conventional Graphite Paper 3

T62, made by T-Global, is a 100% natural graphite paper sold as a thermal interface pad which is 130 microns (5 mils) thick.

TABLE I

| | | | | In |
|---|---|---|---|---|
| | | | Through | Plane Thermal |
| | Thick- | Den- | Plane Thermal | Conductivity, |
| | ness | sity | Conductivity | Isotropic Method |
| Sample | (um) | (g/cc) | (W/mK) | (W/mK) |
| Example 1 | 61.6 | 1.8 | 3.44 | 540.00 |
| Example 2 | 57.8 | 1.8 | 1.43 | 479.00 |
| Example 3 | 72.6 | 1.6 | 3.18 | 484.10 |
| Example 4 | 55.7 | 1.9 | 1.55 | 436.00 |
| Example 5 | 60.7 | 1.4 | 5.93 | 345.00 |
| Conventional | 126.2 | 1.1 | 3.51 | 314.00 |
| Graphite Paper 1 | | | | |
| Conventional | 64.0 | 1.5 | 2.09 | 320.00 |
| Graphite Paper 2 | | | | |
| Conventional | 125.2 | 1.5 | 3.51 | 303.00 |
| Graphite Paper 3 | | | | |

All thermal conductivity values were measured on one inch free standing coupons using a Netzsch LFA 447, which measures thermal conductivity based on the laser flash method. All densities were calculated using a VeriTas analytical balance and an Oakland Instruments thickness gauge.

What is claimed is:

1. Resin free flexible composites of graphite leaf, containing fillers selected from the group consisting of:
i. fibers,
ii. powders, and,
iii. flake.

2. The flexible composite as claimed in claim 37 wherein said non-natural graphite filler content is from 0.1 weight % to 80 weight % based on the total weight of said graphite leaf and non-natural, graphite filler.

3. The flexible composite as claimed in claim 37 wherein said non-natural, graphite filler content is from 0.5 weight to 60 weight % based on the total weight of said graphite leaf and non-natural, graphite filler.

4. The flexible composite as claimed in claim 37 wherein said non-natural, graphite filler content is from 1 weight % to 40 weight % based on the total weight of said graphite leaf and non-natural, graphite filler.

5. The flexible composite as claimed in claim 37 wherein said non-natural, graphite filler content is from 2 weight % to 30 weight % based on the total weight of said graphite leaf and non-natural, graphite filler.

6. A flexible composite as claimed in claim 1 comprising natural graphite and filler materials which have an in-plane thermal conductivity higher than 400 W/mK and a thickness thinner than 100 um.

7. The flexible composite as claimed in claim 1 wherein said graphite and said fillers are heterogeneous across the width of said composite.

8. The flexible composite as claimed in claim 37 wherein said flexible composite is compressed.

9. The flexible composite as claimed in claim 37 wherein said composite has various shapes.

10. The flexible composite as claimed in claim 37 comprising natural graphite and non-natural, graphite filler materials which have in-plane thermal conductivity higher than 400 W/mK.

11. The flexible composite as claimed in claim 10 with a thickness ranging from 5 um to 1000 um.

12. The flexible composite as claimed in claim 10 with a thickness ranging from 10 um to 800 um.

13. The flexible composite as claimed in claim 10 with a thickness ranging from 15 um to 600 um.

14. The flexible composite as claimed in claim 10 with a thickness ranging from 20 um to 400 um.

15. The flexible composite as claimed in claim 10 with a thickness ranging from 25 um to 300 um.

16. A thermal management system as claimed in claim 15 designed for portable electronics devices.

17. The flexible composite as claimed in claim 37 wherein there is a first side and a second side and said first side of said composite has more graphite and said second side has more non-natural, graphite filler than said first side.

18. The flexible composite as claimed in claim 37 wherein there is a first side and a second side, said graphite is predominantly on said first, side of said leaf, and said non-natural, graphite filler material is predominantly on said second side and said graphite and said non-natural, graphite filler are interpenetrating.

19. The flexible composite as claimed in claim 37 wherein said composite consists of a graphite rich layer in a first composition with more than 80% of graphite in said first composition and a non-natural, graphite filler rich layer in a second composition with more than of non-natural graphite filler material in said second composition.

20. The flexible composite as claimed in claim 37 wherein said composite consists of a layer in which the ratio of graphite and non-natural, graphite filler material changes throughout the thickness direction.

21. The flexible composite as claimed in claim 37 wherein the thermal conductivity in the through-plane direction is higher than the thermal conductivity in the through-plane direction of a 100% graphite composite.

22. A thermal management system comprising a flexible composite of claim 37, wherein a graphite surface of said flexible composite is in thermal contact with a heat source from a heat generating device.

23. The thermal management system as claimed in claim 22 in a portable electronic device.

24. The thermal management system as claimed in claim 22 in an LED device.

25. The thermal management system as claimed in claim 22 in an industrial device.

26. The thermal management system as claimed in claim 22 in a medical device.

27. The thermal management system as claimed in claim 22 in a military device.

28. The thermal management system as claimed in claim 22 in a device for aerospace vehicles.

29. The thermal management system as claimed in claim 22 in a device for automotive vehicles.

30. The thermal management system as claimed in claim 22 in a device for train systems.

31. The flexible composite as claimed in claim 37 comprising two natural graphite layers and non-natural, graphite filler materials, each having surfaces, wherein said non-natural, graphite filler surfaces are in thermal contact with two independent thermal sources.

32. The thermal management system as claimed in claim 22 comprising said flexible composite wherein said two graphite surfaces are in thermal contact with two thermal sources.

33. The thermal management system as claimed in claim 32 wherein said thermal sources are batteries.

34. A method of forming a flexible composite as claimed in claim 37 wherein said flexible composite is formed by compressing graphite and at least one non-natural, graphite filler material together.

35. The flexible composite as claimed in claim 37 wherein said graphite is exfoliated.

36. A method of forming a flexible composite as claimed in claim 37 wherein said graphite and said non-natural fillers are deposited from a slurry and then compressed.

37. A method of forming a flexible composite as claimed in claim 36 wherein said slurry is partially segregated to form a heterogeneous composite.

38. A resin-free flexible composite of graphite leaf containing non-natural, graphite fillers, said non-natural, graphite fillers being selected from the group consisting essentially of: fibers, fibrils, powders, particles, and, flakes, said flexible composite having a predetermined width, wherein said graphite and said non-natural, graphite fillers are heterogeneous across said width of said composite.

39. A thermal management system comprising a flexible composite of claim 37, wherein there are two graphite surfaces and said two graphite surfaces are in thermal contact with two thermal sources.
